(19) United States
(12) Patent Application Publication
(10) Pub. No.: US 2024/0331979 A1
(43) Pub. Date: Oct. 3, 2024

(54) Apparatus and Methods for Plasma Processing

(71) Applicant: Tokyo Electron Limited, Tokyo (JP)

(72) Inventors: Sergey Voronin, Albany, NY (US); Hamed Hajibabaeinajafabadi, Albany, NY (US); Qi Wang, Albany, NY (US); Andrew Metz, Albany, NY (US)

(21) Appl. No.: 18/295,144

(22) Filed: Apr. 3, 2023

(51) Int. Cl. H01J 37/32; H01L 21/311

(52) U.S. Cl. CPC H01J 37/32422; H01J 37/3244; H01L 21/31116; H01J 37/32091; H01J 37/321; H01J 2237/024; H01J 2237/332; H01J 2237/3344; H01J 2237/3345

(57) ABSTRACT

An apparatus for plasma processing a substrate includes a substrate holder to hold the substrate in a first portion of a vacuum chamber, and a mesh assembly segregating the first portion from a second portion of the vacuum chamber along a vertical direction, where the mesh assembly includes a vertical stack of planar meshes. The apparatus includes a mesh positioning equipment to horizontally move one of the planar meshes to adjust a vertical permeability of the stack, and a plasma generation equipment to generate plasma in the second portion of the vacuum chamber.

### TECHNICAL FIELD

The present invention relates generally to an apparatus and method for processing a substrate and, in particular embodiments, to apparatus and methods for plasma processing.

### BACKGROUND

Plasma processing is widely used, particularly in integrated circuit (IC) manufacturing. An IC is a network of electronic components formed in a monolithic structure of patterned layers in a substrate. During IC fabrication, semiconductor substrates are processed through a series of patterning levels where, at each level, layers of various materials may be deposited and patterned using lithography and etch processes that transfer a pattern of actinic radiation to targeted layers. Many of the deposition and etch processes use plasma, where ions and radicals from a gas discharge modify the surface physically and chemically. Identical copies of the radiation pattern are printed on the substrate by using a step-and-repeat technique to expose a coating of photoresist, thus forming a matrix of IC units on each substrate after processing through all the patterning levels. In order to lower unit cost, a component density in the ICs is doubled at each new technology node. Generally, this is achieved by shrinking patterned dimensions and using complex three-dimensional (3D) devices such as the nanosheet transistor and vertical NAND (V-NAND) memory that are enabled by advances in patterning technology. The fabricated features have a wide range of aspect ratios and diverse material stacks, for which an equally diverse set of plasma processes may be needed, making it difficult to provide manufacturing efficiency at low cost. To meet this challenge, innovations in plasma technology are desired that provide apparatus and methods with enhanced flexibility and control over plasma properties such as electron temperature, ion flux, and radical flux.

### SUMMARY

An apparatus for plasma processing a substrate includes a substrate holder configured to hold the substrate in a first portion of a vacuum chamber, and a mesh assembly segregating the first portion from a second portion of the vacuum chamber along a vertical direction. The mesh assembly includes a vertical stack of planar meshes. The apparatus includes a mesh positioning equipment configured to horizontally move one of the planar meshes to adjust a vertical permeability of the stack, and a plasma generation equipment configured to generate plasma in the second portion of the vacuum chamber.

A method for plasma processing a substrate includes positioning one of the planar meshes in the associated plane of the mesh, where the positioning adjusts a vertical permeability of the stack. The method includes loading a substrate on a substrate holder in a first portion of a vacuum chamber, where the first portion is segregated from a second portion of the vacuum chamber along a vertical direction by a mesh assembly, which includes a vertical stack of planar meshes. After completing the positioning, the method includes exposing the substrate to an ion flux and a radical flux from a plasma generated in the second portion of the vacuum chamber, where the ion flux and the radical flux are based on the vertical permeability of the stack.

A method for plasma processing a substrate includes loading a substrate on a substrate holder in a first portion of a vacuum chamber, where the first portion is segregated from a second portion of the chamber along a vertical direction by a mesh assembly, which includes a vertical stack of planar meshes. The vertical stack has an adjustable vertical permeability. The method includes performing, in situ, a number of cycles of a process sequence, where the sequence includes setting the vertical permeability of the stack to a first vertical permeability, and exposing the substrate to a first ion flux and a first radical flux for a first time duration, where the first ion and radical fluxes are based on the first vertical permeability. The sequence includes setting the vertical permeability of the stack to a second vertical permeability, and exposing the substrate to a second ion flux and a second radical flux for a second time duration, where a difference between the first ion and radical fluxes and the second ion and radical fluxes is based on a difference between the first vertical permeability and the second vertical permeability.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1C illustrate various schematic views of a plasma processing apparatus in an inductively coupled plasma (ICP) configuration, in accordance with some embodiment;

FIGS. 2A-2C illustrate various planar views of a stack of meshes of a plasma processing apparatus, in accordance with some embodiment;

FIG. 3 illustrates a flowchart for a method for plasma processing a substrate, in accordance with some embodiment;

FIG. 4 illustrates a flowchart for another method for plasma processing a substrate, in accordance with some embodiment; and

FIG. 5 illustrates a schematic view of a plasma processing apparatus in a capacitively coupled plasma (CCP) configuration, in accordance with some embodiment.

### DETAILED DESCRIPTION OF ILLUSTRATIVE EMBODIMENTS

In plasma processing, the surface of a substrate is modified by exposing it to an ion flux (Γᵢ) and a radical flux (Γᵣ) provided by plasma generated by plasma generation equipment of a plasma processing apparatus. The embodiments of plasma processing apparatus and methods, described in this disclosure, provide controlled ion and radical fluxes that may be adjusted to adjust a ratio of the ion flux to the radical flux (Γᵢ/Γᵣ) over a wide range.

Typically, in plasma processing, the electric and magnetic fields of an electromagnetic (EM) signal coupled to a gas flowing through a vacuum chamber may impart energy to ionize a fraction of the gas to form a plasma discharge containing positively charged ions, negatively charged free electrons, and neutral radicals, although most of the gas molecules may remain at low energies in equilibrium with an ambient temperature in the chamber. Free electrons, being light and mobile, get rapidly accelerated and reach a very high effective electron temperature relative to the other particles in the gas, for example, ten times to a hundred times higher than the ambient temperature. The high energy free electrons may interact with the surrounding gas, in a distance of a mean free path, to create new free electron-ion pairs as well as free radicals, which are atoms or groups of atoms having bound electrons in excited electronic states. Generally, the radicals (being charge neutral) flow primarily by diffusion and are directed by the gas flow, while the charged particles (ions and free electrons) move primarily by drift and are directed by the electric field. This electric field is weak in a central quasi-neutral region of the plasma but strong in a space-charge region near the periphery of the plasma, referred to as the plasma-sheath, where the positive ions get accelerated outward while the negative free electrons are pushed inward.

The radicals in the plasma, having unpaired electrons in excited states, are very reactive. Thus, a flux of radicals toward the substrate may react with other elements present in the gas and the substrate, generating reaction products that may chemically modify the surface. For example, a gas phase reaction involving radicals from a precursor gas may be used in a plasma-enhanced chemical vapor deposition (PECVD) process to deposit silicon oxide on the surface. In another example, a silicon layer may be etched during a plasma process, where fluorine radicals react with the surface silicon to form volatile byproducts comprising silicon compounds that are removed with the gas flow.

Ions, on the other hand, may modify the surface physically as well as chemically. Being charged particles, ions may be accelerated by the sheath electric field and acquire high enough momentum to break electronic bonds and dislodge atoms, thereby physically modifying the substrate. In addition, by breaking electronic bonds, the ions facilitate chemical reaction with the substrate material, including the chemical interaction with radicals. For example, the reaction rate, during a reactive ion etch (RIE) process, may slow down excessively if the ion flux is greatly reduced.

The angular distributions of the kinetic energies of the ions and the radicals determine a directionality or anisotropy of the associated plasma process. The momentum distribution in the ion flux, generally, has a large directional component parallel to the electric field, with only a small fraction of the kinetic energy being distributed in all directions by randomizing collisions. In contrast, the momentum distribution in the radical flux has a large random component, which is understood since the radicals move primarily by diffusion, which is a random walk process.

The properties of the ion flux (Γᵢ) and the radical flux (Γᵣ), as discussed briefly above, makes the ion-to-radical flux ratio (Γᵢ/Γᵣ) a plasma parameter of importance for plasma processes used in a fabrication flow, as explained in further detail below.

For example, as known to persons skilled in the art, it is advantageous to fabricate metal lines with vertical sidewalls. Metal lines of a standard damascene metal interconnect level are inlaid in an interlevel dielectric (ILD) layer comprising, for example, silicon oxide. A fabrication flow for damascene metal interconnect may comprise etching trenches in the ILD layer, overfilling the trenches with metal comprising, for example, copper, and removing excess metal from over the top of the ILD to form the inlaid metal lines. For the metal lines to have vertical sidewalls, the trenches are typically etched using an anisotropic RIE process having a vertical etch profile. To achieve the anisotropy, a plasma process with a high ion-to-radical flux ratio Γᵢ/Γᵣ may be needed to effectively utilize the directionality of the ion flux to provide the desired vertical trench sidewalls. In contrast, a low ion-to-radical flux ratio Γᵢ/Γᵣ may be needed for a plasma process used to form a liner after etching trenches in the ILD layer, as explained below.

Before filling the trenches with copper, a liner comprising a diffusion barrier material is deposited over the surface, including the walls of the trenches. To block out-diffusion of copper, the liner needs to be a film free of defects such as pinholes and cracks. To achieve this, the deposition process has to form a continuous, conformal film with good step coverage and uniformity. In addition, the liner has to be thin, its thickness being limited by an upper bound on electrical resistance of minimum width metal lines. To meet these constraints, a plasma-enhanced atomic layer deposition (PEALD) process may be used. Because a highly conformal thin film is to be deposited, it is undesirable to have ions bombarding a surface of the liner during deposition. Thus, the PEALD process may need to control the ion-to-radical flux ratio (Γᵢ/Γᵣ) to a very low value.

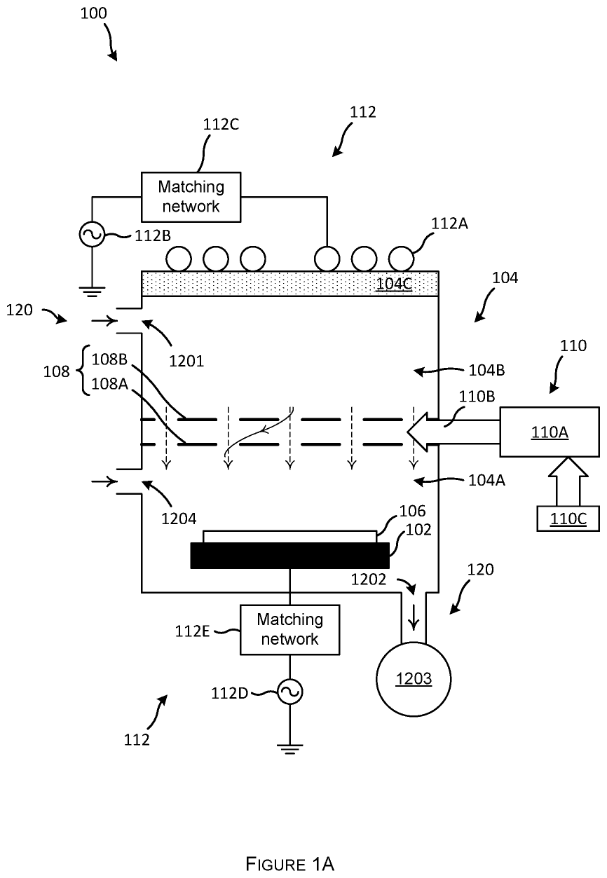

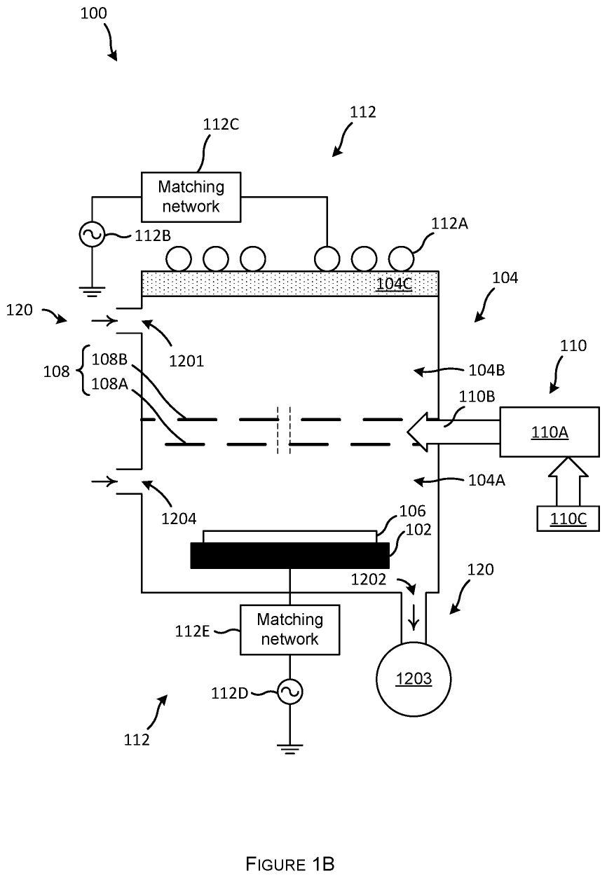

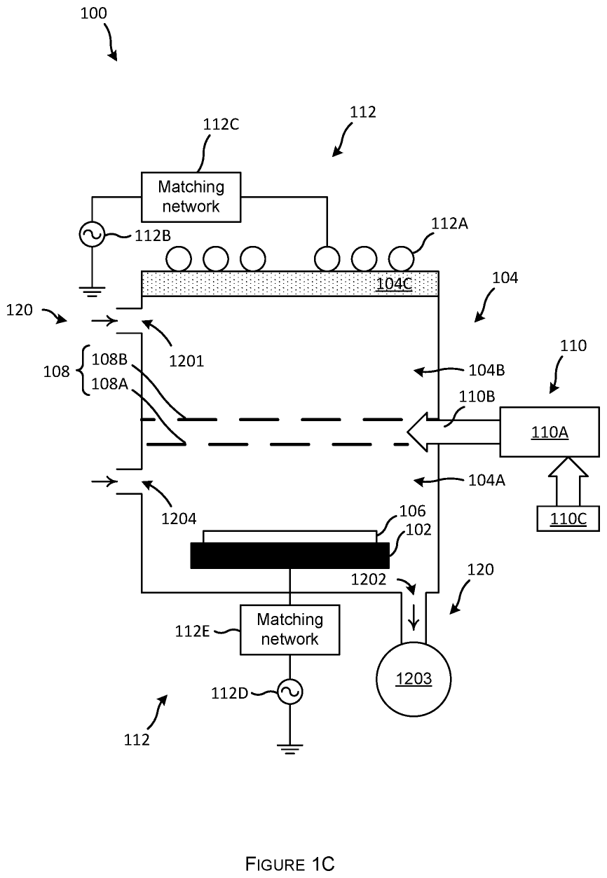

It is understood from these examples of plasma processes that it is advantageous to have plasma processing apparatus and methods with which the ion-to-radical flux ratio Γᵢ/Γᵣ may be adjusted over a wide range. In this disclosure, we describe embodiments of apparatus and methods to adjust the ion flux (Γᵢ) and the radical flux (Γᵣ), hence the ion-to-radical flux ratio Γᵢ/Γᵣ by positioning meshes of a mesh assembly comprising a stack of meshes inserted in a vacuum chamber used for the plasma processing to segregate the chamber into two portions, with the mesh assembly in the middle. As explained further below with reference to FIGS. 1A-1C, the ion flux is more sensitive to the positioning and may be reduced from a maximum value to over several orders of magnitude lower. Hence, by positioning the meshes appropriately, the ion-to-radical flux ratio may be adjusted from a maximum value to a minimum value close to zero (i.e., almost no ions emerging from the mesh assembly). Even when the mesh assembly is configured for the maximum value of the ion-to-radical flux ratio, the mere presence of the mesh assembly would cause some lowering of the ion-to-radical flux ratio relative to the ratio without a mesh assembly. If the ion-to-radical flux ratio with no mesh is taken as a reference value then the maximum value of the ion-to-radical flux ratio may be about 75% to about 95% of the reference value and the minimum value of the ion-to-radical flux ratio may be about a millionth to about a trillionth of the reference value.

FIG. 1A illustrates a schematic view of an example plasma processing apparatus 100, where the ion flux and the radical flux, hence the ion-to-radical flux ratio (Γᵢ/Γᵣ) may be adjusted by positioning meshes of a mesh assembly.

In FIG. 1A, the plasma processing apparatus 100 is shown having a substrate holder 102 inside a vacuum chamber 104. As illustrated in FIG. 1A, the substrate holder 102 may have an electrostatic chuck configured to hold a substrate 106, for example, hold a semiconductor wafer. In addition to the electrostatic chuck, the substrate holder 102 may include components for heating and cooling to control a temperature of the substrate 106 during processing.

Inside the chamber 104, is a mesh assembly 108. The mesh assembly 108 segregates a first portion 104A of the chamber 104 from a second portion 104B of the chamber with a vertical stack of planar meshes, where the first portion 104A is where the substrate holder 102 is located. The stack includes a first mesh 108A and a second mesh 108B. As illustrated in FIG. 1A, the holes of the first mesh 108A are contiguous with the first portion 104A, and the holes of the second mesh 108B are contiguous with the second portion 104B. Thus, gas may flow through the mesh assembly via the holes of the meshes.

In the example embodiment illustrated in FIG. 1A, the meshes, such as the first mesh 108A and the second mesh 108B, may comprise a perforated sheet of an insulating material such as alumina, quartz, or some other type of ceramic, or the like. In some other embodiments, the mesh may comprise a conductive material with an insulating coating (e.g., anodized aluminum, metal coated with yttria, etc.). In some embodiments, where the mesh comprises a conductive material with an insulating coating, the mesh may be used as an electrode coupled, for example, an RF bias source, a pulsed RF bias source, a pulsed DC bias, or a combination thereof.

The example plasma processing apparatus 100 in FIG. 1A has two meshes in the mesh assembly 108. However, it is understood that, in some other embodiment, the number of meshes may exceed two. The shape of the meshes may be selected depending on the shape of the chamber 104. Rectangular sheets may be selected as meshes for a stack intended to be placed in a chamber 104 shaped as a rectangular cylinder, and disc-shaped sheets may be selected as meshes for a stack intended to be placed in a circular cylindrical chamber 104. The meshes in the example mesh assembly 108 are shown to be of identical geometrical design. In other embodiments, different mesh designs may be used for different meshes. The geometrical parameters used in the mesh design may include a shape of the holes (e.g., circular, square, oblong, etc.), dimensions of the hole, and a distance separating adjacent holes. Furthermore, each mesh of the stack of meshes in the example mesh assembly 108, illustrated in FIG. 1A, has uniform density of holes. In some other embodiment, the density of holes may be nonuniform. For example, the mesh may have a first density in a central region of the mesh and a second density in an edge region of the mesh to help reduce center-to-edge nonuniformity in ion-to-radical flux ratio, during processing.

In addition to the meshes, the mesh assembly 108 includes fixtures (not shown) that function to hold the meshes with fixed vertical separations between adjacent meshes. In some embodiments, a vertical position of the mesh assembly 108 (including all the meshes of the vertical stack) may be adjustable to adjust a ratio of a volume of the first portion 104A to a volume of the second portion 104B. In some embodiments, a mesh may be added, removed, or replaced with another mesh. In order to reduce a risk of particulate contamination of the substrate 106 while adding, removing, or replacing one of the meshes it is preferred that these operations not be performed when the substrate 106 is inside the chamber 104.

Although the mesh assembly 108 segregates a first portion 104A of the chamber 104 from a second portion 104B, gas may flow through the mesh assembly 108 along paths via the holes of the meshes. Some of these paths are in a direct line-of-sight between the first portion 104A and the second portion 104B, as indicated by vertical dashed arrows in FIG. 1A. The vertical line-of-sight paths provide vertically moving particles a passage through the mesh assembly 108 to the substrate 106 via vertically overlapping holes of the meshes. Pathways via non-overlapping holes, (e.g., the path indicated by a curved solid arrow in FIG. 1A) are not easily accessible to charged particles such as ions and electrons due to their ambipolar diffusion and excessive loss on the mesh wall. However, such a path may be accessed by neutral particles (e.g., radicals), which are in a diffusion flow, which is a random walk process, as explained above. Hence, as expected, the ion flux, Γᵢ, is more sensitive to the overlap than the radical flux, Γᵣ, and the ion-to-radical flux ratio, Γᵢ/Γᵣ, may be varied by varying the overlap, as is done in the embodiments described in this disclosure.

In this disclosure, a cross-sectional area of the vertical line-of-sight paths between the first portion 104A and the second portion 104B is referred to as a vertical permeability of the stack of meshes. Accordingly, the vertical permeability is a measure of the geometrical transparency of the stack. For example, in the configuration of the mesh assembly 108 illustrated in FIG. 1A, the vertical permeability is the maximum for this stack since the meshes are aligned such that each hole of the first mesh 108A is exactly below the respective hole of the second mesh 108B. Since both meshes have the same design, this maximum value is equal to the total area of the holes in one mesh. In the embodiments of plasma processing apparatus in this disclosure, the stack has a movable mesh. By moving the mesh in the associated plane of the mesh, the vertical permeability may be adjusted to a value ranging from the maximum value (i.e., maximum overlap of holes) to zero (i.e., no vertical line-of-sight path through the mesh assembly 108). In an embodiment where the stack has more than two meshes, there may be more than one movable mesh.

Generally, reducing the vertical permeability reduces the ion flux. However, the ion flux may not be directly proportional to the vertical permeability of the stack. For example, the ion flux may have a non-zero residual value even if the vertical permeability is set to zero. The non-zero ion flux, is because a non-zero fraction of ions suffer randomizing collisions and are able to pass through the mesh assembly 108 via non-overlapping holes. Although the transport of charged particles is generally a drift mechanism, both charged and neutral particles have a diffusion component in the transport through the mesh assembly 108.

Ions and free electrons may be generated in a volume comprising bulk plasma. Thus, in general, charged particles may be generated not only in the second portion 104B but also in the first portion 104A. Typically, lifetimes of the charged particles are much shorter than that of the neutral radicals. In addition, lifetimes of the charged species in quasi-neutral regions, such as bulk plasma, are mostly defined by ambipolar diffusion. Therefore, segregating the chamber 104 into the first portion 104A and the second portion 104B by the mesh assembly 108 is like “breaking” the volume of plasma into two volumes. This significantly reduces charge particle generation in the first portion 104A, resulting in a dramatic decrease of the ion density and flux in that volume.

Unlike ions, a large fraction of the radicals are moving in random directions. Accordingly, the radical flux is less sensitive to the vertical permeability of the stack. Since the radical flux Γᵣ reduces more slowly than the ion flux Γᵢ as the vertical permeability is reduced, ion-to-radical flux ratio Γᵢ/Γᵣ also reduces. Hence the ion-to-radical flux ratio, Γᵢ/Γᵣ, may be varied by varying vertical permeability. As mentioned above, ion-to-radical flux ratio may be varied from a maximum value of about 75% to 95% of the reference value to a minimum value of about a millionth to a trillionth of the reference value, where the reference value is the ion-to-radical flux ratio in the absence of the mesh assembly 108.

The mesh assembly 108 may be designed to allow one of the two planar meshes (e.g., the first mesh 108A) to have one degree of freedom to move in its associated horizontal plane. For example, the mesh may be placed on a track in the mesh assembly 108 and its position altered by, for example, rotating the mesh about its vertical central axis, or sliding the mesh along a fixed horizontal direction. By altering the relative position of the two meshes, it is possible to vary their vertical alignment to provide a variable permeability for the stack.

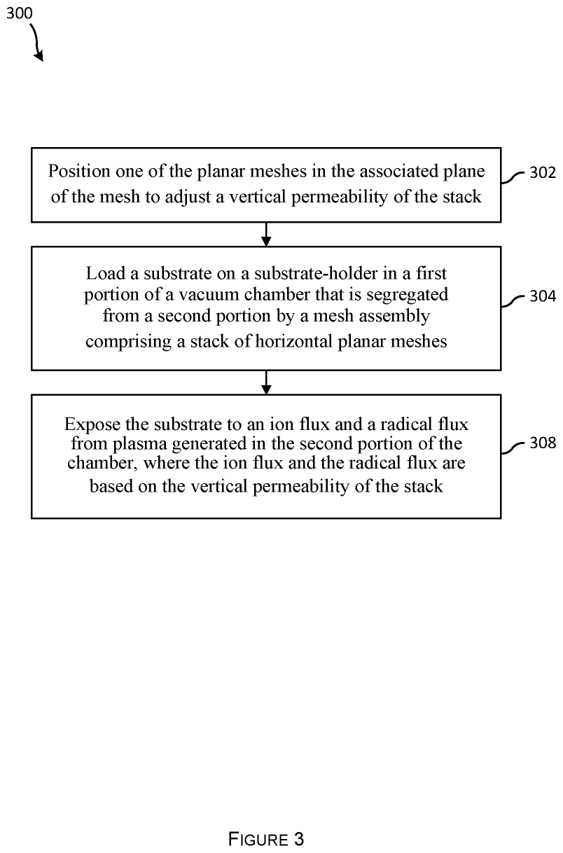

Configuring the mesh assembly 108 to provide a fixed permeability during processing is preferably done with no substrate in the chamber 104 (as in a method 300, described further below with reference to FIG. 3) in order to minimize unintended particulate contamination. Thus, the method 300 may be used, for example, for pre-setting the mesh assembly 108 at the equipment manufacturing factory for the plasma processing apparatus 100 to be used for a specific plasma process at the IC fabrication facility. Additionally, the method 300 provides a flexibility of reconfiguring the mesh assembly 108 at the IC fabrication facility for the plasma processing apparatus 100 to be used for multiple plasma processes.

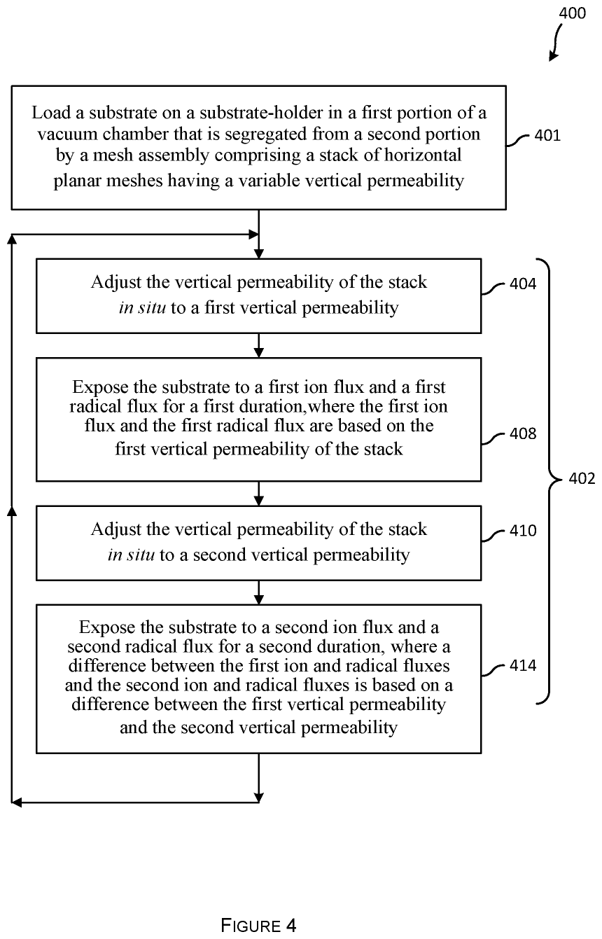

However, in some other embodiment, the order of loading the substrate into the chamber and positioning the meshes may be reversed. For example, in a method 400, described further below with reference to FIG. 4, the mesh assembly 108 may be configured while the substrate 106 is in the chamber 104. Thus, in the method 400, the mesh assembly 108 may be reconfigured to alter the permeability of the stack dynamically during processing, albeit at the cost of an increased risk of particulate contamination. This capability is advantageous to a plasma process, where it is desirable to alter the ion-to-radical flux ratio at various stages of processing. In contrast, method 300 provides the advantage of reduced risk of particulate contamination but is limited to static processing, where the permeability of the stack is fixed during processing.

As shown schematically in FIG. 1A, the plasma processing apparatus 100 includes mesh positioning equipment 110 to position one of the planar meshes in the associated plane. As mentioned above, the mesh positioning equipment 110 may be operated for pre-setting the mesh assembly 108 at the equipment manufacturing factory or at the IC fabrication facility for the plasma processing apparatus 100 to be used for multiple plasma processes. Furthermore, the mesh positioning equipment 110 may be operated while the substrate 106 is in the chamber 104 for in situ process adjustment.

The mesh positioning equipment comprises an actuator 110A located outside the chamber 104. The actuator 110A may be, for example, a rotor or a retractor. The actuator 110A is coupled by movable parts to the mesh assembly 108 and configured to move the parts to position one of the movable meshes in its associated horizontal plane. For example, the actuator 110A may be moving a mechanical coupler 110B (indicated schematically by a block arrow in FIG. 1A). The mechanical coupler 110B couples the actuator 110A to other movable parts (not shown) using, for example, a bar link or a belt-and-pulley system. The actuator 110A and the moving parts, such as gears, hinges, bar links, ball bearings, and the like together move one of the movable meshes to adjust the vertical permeability of the stack of meshes. Some of the movable parts may be inside the chamber 104 and accessed via a feedthrough. In some embodiments, the mesh positioning equipment 110 may include a controller 110C, configured to send control signals to the actuator 110A, and the actuator 110A may be configured to receive the control signals and perform the positioning accordingly.

Still referring to FIG. 1A, the plasma processing apparatus 100 includes plasma generation equipment 112, configured to generate plasma in the chamber 104. As mentioned above, plasma processing is done using gas discharge plasma. So, the plasma generation equipment 112 includes a gas flow system 120, configured to flow gas through the chamber 104. The gas flow system 120, seen in FIG. 1A, has a gas inlet 1201, a gas outlet 1202, and a vacuum pump 1203 coupled to the gas outlet 1202 to pump gas out of the chamber 104. Although one gas inlet 1201 is shown coupled to the second portion 104B of the chamber 104 via an opening in a sidewall of the chamber 104, it is understood that there may be multiple gas inlets coupled to the second portion 104B of the chamber 104 and various types of gas inlet designs (e.g., a showerhead in a top cover of the chamber 104). Likewise, although one gas outlet 1202 is shown coupled to the first portion 104A of the chamber 104 via an opening in a bottomwall of the chamber 104, it is understood that there may be multiple gas outlets coupled to the first portion 104A of the chamber 104.

In some embodiments, in addition to the gas inlet 1201 coupled to the second portion 104B, there may be an additional gas inlet (e.g., the additional gas inlet 1204 in FIG. 1A) coupled to the first portion 104A to provide additional flexibility to adjust the ion and radical fluxes to the substrate 106. For example, argon gas may be introduced into the volume of the second portion 104B to be ionized there, while a process gas for supplying radicals, for example, nitrogen trifluoride (NF₃) may be introduced into the first portion 104A through the additional gas inlet 1204. Since the free electrons in the first portion 104A have relatively lower electron temperature, the frequency of dissociative electron attachment (DEA) reactions would be enhanced, resulting in an effective fluorine radical (F*) generation, while reducing substrate surface or wafer mask erosion by ion collisions.

The gas, introduced in the chamber 104 through the gas inlet 1201, may be a mixture of various gases such as reactants, diluents, and additives. The gas pumped out of chamber 104 through the gas outlet 1202 may further include volatile byproducts generated in the chamber 104 during processing. In the embodiments described in this disclosure, inside the chamber 104, the gas flow has to be directed from the second portion 104B, into the mesh assembly 108 through the second mesh 108B, and out of the mesh assembly 108 through the first mesh 108A toward the substrate 106. Thus, at least one gas inlet, such as the gas inlet 1201 is coupled to the second portion 104B. All gas outlets, such as the gas outlet 1202 are coupled to the first portion 104A of the vacuum chamber 104. Other components of the gas flow system 120 may include gas canisters, flow lines, throttle valves, gas flow sensors and controllers, and the like.

A gas discharge is ignited and sustained by ionizing the gas introduced into the second portion 104B of the chamber 104 using electromagnetic (EM) power. Accordingly, the plasma generation equipment 112 includes a first electrode 112A configured to couple EM power to the gas in the chamber from a first EM power source 112B. Generally, the first EM power source 112B provides source power at a radio frequency (RF) in a range of 400 kHz to 5 GHz. The first electrode 112A is a power coupler by which EM power is coupled to plasma in the chamber 104. Thus, source power from the first EM power source 112B is coupled to the first electrode 112A via a first impedance matching network 112C for efficient coupling and to suppress undesired reflected power. Depending on the configuration of the plasma generation equipment, different types of power couplers may be used, such as planar coil or helical coil antennas located outside the chamber 104 or planar disc-shaped electrode inside the chamber 104.

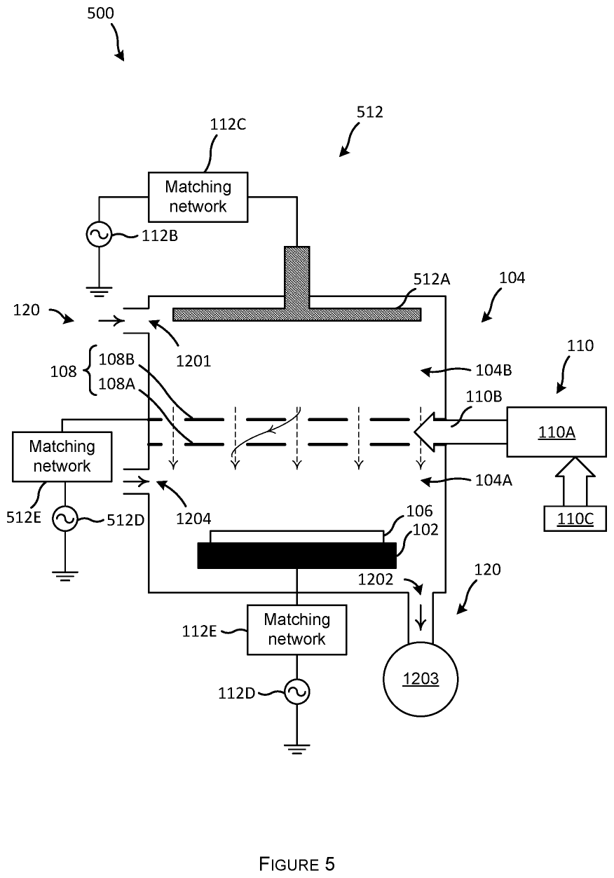

Generally, the plasma generation equipment may be having various configurations. For example, in FIG. 1A, the plasma generation equipment 112 of the example plasma processing apparatus 100 is configured in an inductively coupled plasma (ICP) mode, whereas the plasma generation equipment 512 of the plasma processing apparatus 500 (described in further detail below with reference to FIG. 5) is configured in a capacitively coupled plasma (CCP) mode. Typically, in the ICP configuration, the first electrode 112A is an antenna outside the chamber 104. For example, as illustrated in FIG. 1A, the first electrode 112A is a planar coil placed over a top cover 104C of the chamber 104. EM power is coupled through the top cover 104C to ionize the gas in the second portion 104B inside the chamber 104, similar to transmitting an EM signal from an antenna to a remote location. In order to avoid shielding electromagnetic fields, conductive material is not used in the top cover 104C between the first electrode 112A and the second portion 104B; typically, the top cover 104C comprises a dielectric such as quartz.

In some embodiments, the plasma generation equipment may have a second electrode to provide RF bias power, a pulsed-DC bias, a DC bias, or a reference potential (often referred to as ground) to direct the flux of ions toward the substrate 106. In the example embodiment of plasma processing apparatus 100, the substrate holder 102 of the plasma generation equipment 112 has been be configured to be used as the second electrode. As illustrated in FIG. 1A, an RF bias source 112D is coupled to the substrate holder 102 via a second impedance matching network 112E. In various embodiments, the bias source may be an RF bias source, a pulsed RF bias source, a pulsed DC bias, a DC bias, ground, or a combination thereof.

In FIG. 1A, the plasma processing apparatus 100 is in the ICP configuration. In the ICP configuration, plasma is ignited in the second portion 104B close to the first electrode 112A (the planar coil coupling EM power to the gas inside the chamber 104). The ionized gas flows from the second portion 104B into the mesh assembly 108 through the holes of the second mesh 108B. As mentioned above, charged particles move by drift in the electric field and the neutral particles move by diffusion and a pressure gradient created by the vacuum pump 1203. The mobile free electrons may collide with the meshes and some impart negative charge till a steady state is quickly established. The less mobile positively charged ions then collide with the negatively charged mesh surfaces resulting in losses of both ions and electrons on the meshes by ambipolar diffusion. If the geometrical dimension between holes in adjacent meshes is smaller than Debye length of the plasma discharge, this results in complete collapsing of the discharge in the mesh assembly 108 and minimum penetration of the charged particles to the first portion 104A. In other words, a density of ions and a density of free electrons in the second portion 104B are greater than the respective densities in the first portion 104A. Likewise, the effective electron temperature in the second portion 104B is higher than the effective electron temperature in the first portion 104A. Reducing the vertical permeability of the stack of meshes increases the difference between the plasma densities in the two portions of the chamber 104.

The first portion 104A, being the portion where the substrate 106 is held, may be described as a process volume of the chamber 104, and the second portion, being the portion where the plasma is ignited and most dense, may be described as a plasma reactor volume. The source of ions and radicals for the process volume (the first portion 104A) is the fluxes of ions and radicals emerging from the holes of the first mesh 108A of the mesh assembly 108. Thus, adjusting the ion flux Ti and the radical flux Ir by adjusting the vertical permeability of the stack is like adjusting the plasma source for the substrate 106. By including the mesh positioning equipment 110 in the plasma processing apparatus 100, the embodiments described in this disclosure, provide an additional flexibility that is equivalent of changing the plasma source of the plasma processing apparatus 100 at the fabrication facility. As explained above, desired properties of the plasma source for the process volume (the first portion 104A) may be selected conveniently by adjusting the vertical permeability of the stack with the mesh positioning equipment 110, even for very different processes. For example, at one step, the mesh positioning equipment 110 may be operated to configure the mesh assembly 108 for a fin-cut process, a highly anisotropic silicon etch used for fabricating silicon fins protruding from a silicon substrate. At a later step, the mesh assembly 108 may be reconfigured for an isotropic silicon etch such as a nanosheet recess process used to recess alternating nanosheets in a nanosheet transistor stack. Furthermore, the embodiments described herein enable adjusting the plasma properties in situ. The in situ change is enabled, for example, by providing the actuator 110A access to move a movable part inside the vacuum chamber 104. The movable part, when moved, is configured to move one of the planar meshes in the associated plane of the mesh. This provides an opportunity not only for in situ tuning of different process parameters such as anisotropy and selectivity but also for performing in situ cyclic plasma processing, where each cycle of the cyclic process may include more than one plasma process step, as described in further detail below.

In some embodiments, the plasma processing apparatus 100 may include vertical positioning equipment configured to adjust a vertical position of the mesh assembly 108 to adjust a ratio of a volume of the first portion 104A (the process volume) to a volume of the second portion 104B (the plasma reactor volume).

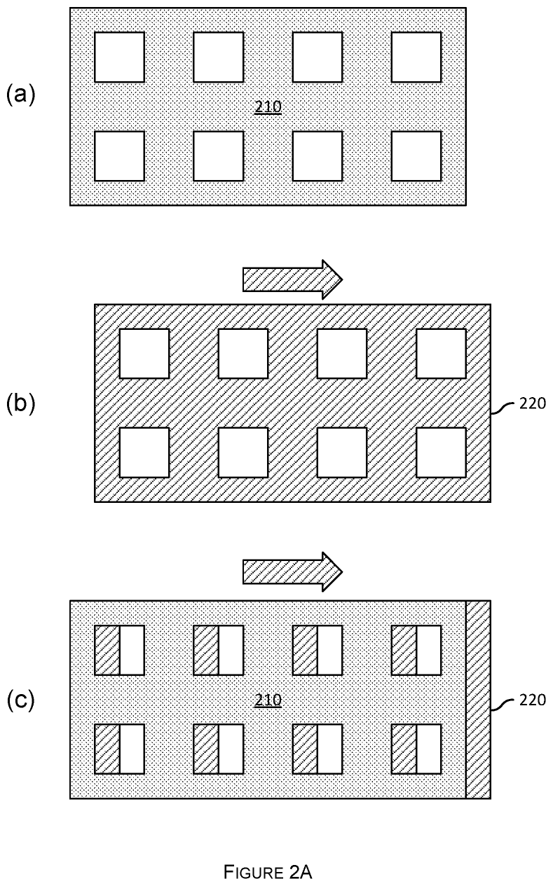

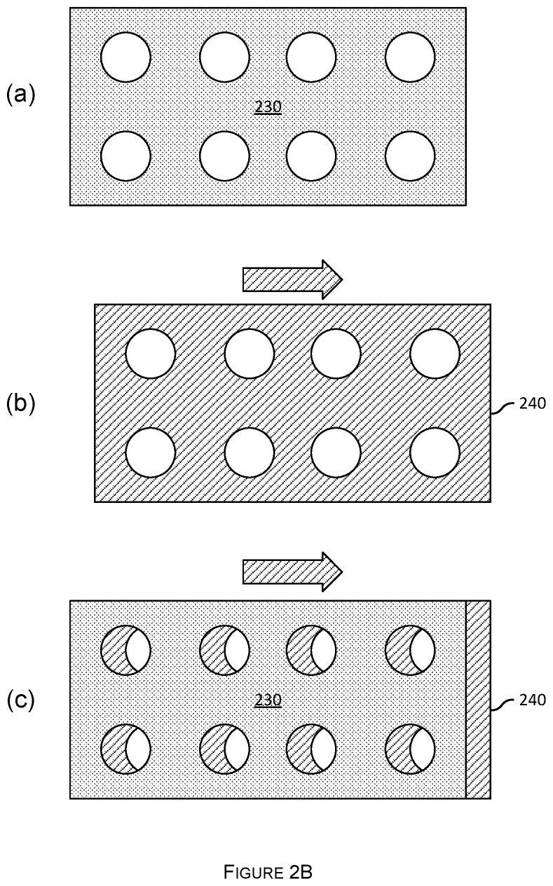

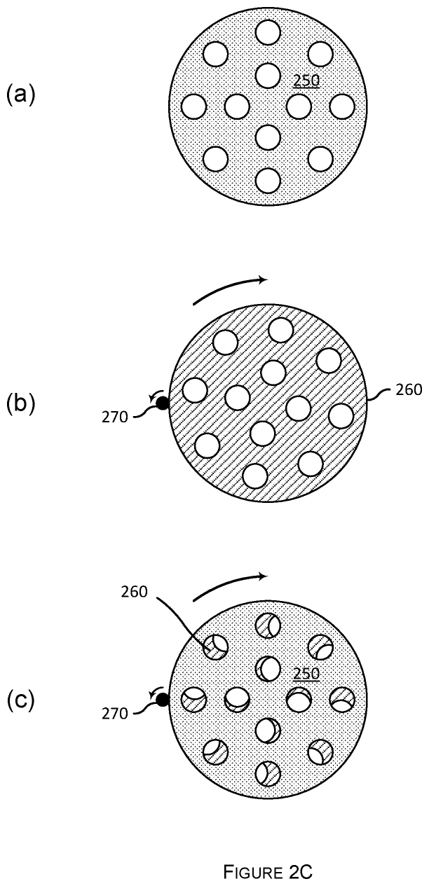

An embodiment of a method 300 for plasma processing a substrate by operating the plasma processing apparatus 100 is described next with reference to FIGS. 1A-1C, FIGS. 2A-2C and a flowchart for the method 300 illustrated in FIG. 3.

FIG. 3 illustrates a flowchart summarizing a method 300 for plasma processing a substrate with the plasma processing apparatus 100. One of the meshes (e.g., the first mesh 108A in FIG. 1A) may be positioned in its associated plane, as indicated in box 302 of the flowchart in FIG. 3 for method 300. As indicated in box 304 of the flowchart in FIG. 3 for method 300, prior to igniting plasma, the substrate 106 may be loaded on the substrate holder 102 (see FIG. 1A). In general, the loading (box 304) and the positioning (box 302) may be performed in any order, for example, positioning one of the meshes first and then loading the substrate 106, as in the flowchart for method 300 in FIG. 3. Here, the positioning is performed while the substrate 106 is outside the chamber 104. Thus, method 300 may be used, for example, for pre-setting the mesh assembly 108 at the equipment manufacturing factory for the plasma processing apparatus 100 to be used for a specific plasma process at the IC fabrication facility. Additionally, the method 300 provides a flexibility of reconfiguring the mesh assembly 108 at the IC fabrication facility for the plasma processing apparatus 100 to be used for multiple plasma processes.

However, in some other embodiment (e.g., the method 400 described in detail further below with reference to FIG. 4), the order may be reversed so that the positioning is performed while the substrate 106 is in the chamber 104. This provides an advantage of dynamically altering a configuration of the mesh assembly 108 during processing.

Typically, the loading is done by a robotic arm transferring the substrate 106 from a load lock chamber to the substrate holder 102 in the first portion 104A via a transfer window.

As described above, positioning one of the planar meshes in the associated plane of the mesh adjusts the vertical permeability of the stack of meshes (box 302) by varying the cross-sectional area of line-of-sight vertical paths passing through the stack. The vertical permeability of the stack is reduced successively from its maximum value in the configuration of the mesh assembly 108 shown in FIG. 1A to a lower value in the configuration shown in FIG. 1B, and to a minimum value of zero in FIG. 1C. As explained above, in the example embodiment of the mesh assembly 108, the cross-sectional area of line-of-sight vertical paths passing through the stack is maximum when holes of the second mesh 108B exactly overlap those of the first mesh 108A (as in FIG. 1A). In FIG. 1B, the first mesh has been shifted to a position where about half of each hole of the second mesh 108B overlaps the respective the overlap hole of the first mesh 108A (as indicated by a pair of vertical dashed lines in FIG. 1B), thus reducing the vertical permeability to half the maximum value. In the configuration shown in FIG. 1C, there is no overlap, hence the cross-sectional area of line-of-sight vertical paths passing through the stack, which is the vertical permeability, is zero. It is noted that, if the vertical permeability is zero then the plasma processing apparatus 100 may be considered as equivalent to a remote plasma processing apparatus, where a plasma source is located remotely and radicals extracted from the plasma source are transported to a processing chamber containing the substrate to be processed.

As mentioned above, positioning one of the meshes comprises operating the mesh positioning equipment 110 (described above with reference to FIG. 1A). Various types of coplanar motion may be generated with the mesh positioning equipment 110.

FIGS. 2A and 2B show top views of meshes in a stack comprising a pair of identical meshes to illustrate linear sliding motion being used to vary the vertical permeability (i.e., the cross-sectional area of line-of-sight paths via overlapping holes of the two meshes). The views from top to bottom in FIG. 2A illustrate (a) a rectangular mesh-A 210 having square holes, (b) a retractable rectangular mesh-B 220 having the same design as the mesh-A 210, except mesh-B 220 has been shifted laterally relative to mesh-A, and (c) mesh-A 210 and mesh-B 220 overlaid on top of each other. FIG. 2B also illustrates linear sliding motion being used to vary the vertical permeability of a stack of two rectangular meshes of identical design, mesh-C 230 and mesh-D 240. The difference is that mesh-C 230 and mesh-D 240 have circular holes. It is noted that for rectangular holes the change in vertical permeability is proportional to the shift but not so for circular holes.

FIG. 2C illustrates a rotary motion being used to vary the vertical permeability of a stack comprising two circular disc-shaped meshes. Similar to the views in FIGS. 2A and 2B, the views from top to bottom in FIG. 2C illustrate (a) a disc-shaped mesh-E 250 having circular holes, (b) a rotatable disc-shaped mesh-F 260 having the same design as the mesh-E 250, except mesh-F 260 has been rotated relative to mesh-A, and (c) mesh-A 210 and mesh-B 220 overlaid on top of each other. The rotation may be achieved by rotating, for example, a gear 270 inside the vacuum chamber (e.g., chamber 140) coupled to the mesh-F 260, as illustrated in FIG. 2C.

The positioning of the meshes to adjust the vertical permeability of the stack of meshes (box 302) configures the mesh assembly 108 to provide a desired plasma environment for processing the substrate 106, i.e., provides desired plasma properties, including a first ion density, a first electron density, a first electron temperature and a first radical density in the first portion 104A of the chamber 104 (the process volume). Along with the various particle densities and temperatures, the vertical permeability controls the ion and radical fluxes (Γᵢ and Γᵣ) directed from the first mesh 108A to the substrate 106.

Thus, after completing the positioning, the plasma generation equipment 112 may be operated to generate plasma. As described above, generating plasma in the vacuum chamber 104 includes flowing gas through the chamber 104 and coupling EM power to the gas from the first electrode 112A to ionize the gas in the second portion 104B (the plasma reactor volume), thus igniting plasma. Once ignited, the plasma extends into the mesh assembly 180 through the holes of the second mesh 108B. As described above, the gas flow system 120 of the plasma generation equipment 112 flows gas into the chamber 104 through the gas inlet 1201 coupled to the second portion 104B and pumps gas out of the chamber 104 through the gas outlet coupled to the first portion 104A. The pumping directs the ion and radical fluxes (Γᵢ and Γᵣ) generated from the plasma in the second portion 104B and exiting the mesh assembly 108 through the holes of the first mesh 108A toward the substrate 106. The ion and radical fluxes are based on the vertical permeability of the stack. By adjusting the vertical permeability, the ion-to-radical flux ratio Γᵢ/Γᵣ may be varied from a maximum value of about 75% to 95% of the reference value to a minimum value of about a millionth to a trillionth of the reference value, where the reference value is the ion-to-radical flux ratio in the absence of the mesh assembly 108.

With the plasma generated and the gas flow established, the substrate 106 may be processed by exposing the substrate 106 to the ion flux and the radical flux for a duration, as indicated by box 308 in the flowchart for method 300 (illustrated in FIG. 3).

Another embodiment of a method for plasma processing a substrate by operating the plasma processing apparatus 100 is a cyclic plasma process 400 described below with reference to FIGS. 1A-1C and a flowchart illustrated in FIG. 4.

In cyclic plasma processing, a substrate is cycled a number of times through a sequence of process steps that may comprise more than one plasma step. Thus, during the execution of the cyclic plasma process, the ion-to-radical flux ratio Γᵢ/Γᵣ may have to be adjusted by positioning one of the meshes in the stack of meshes in situ and new plasma generated at more than one step of the sequence, to meet the requirements of the respective step.

Referring to FIG. 4 and FIGS. 1A-1C, in the cyclic plasma process 400, the substrate 106 is loaded on the substrate holder 102 in the first portion 104A of the vacuum chamber 104, as indicated in box 401 of the flowchart in FIG. 4. As described above with reference to FIG. 1A, the mesh assembly 108 segregates the vacuum chamber 104 into the first portion 104A (the process volume) and the second portion 104B (the plasma reactor volume). With the substrate 106 loaded on the substrate holder 102 in the first portion 104A, a number of cycles of a process sequence 402 may be performed in situ, as illustrated in the flowchart for the cyclic plasma process 400 in FIG. 4.

The process sequence 402 processes the substrate 106 through two different plasma processes. The first plasma process is executed by performing the first two steps in the process sequence 402. In the first step, one of the meshes in the mesh assembly 108 is positioned in situ to adjust the vertical permeability of the stack to a first vertical permeability, as indicated in box 404 of the flowchart for the cyclic plasma process 400 in FIG. 4. After the positioning is complete, a first plasma is generated using the plasma generation equipment 112, as described above with reference to FIG. 1A. The first plasma provides a first ion flux and a first radical flux directed from the first mesh 108A of the mesh assembly 108 to the substrate 106, the fluxes being based on the first vertical permeability, as described above. With the mesh assembly 108 configured to provide the desired plasma environment in the first portion 104A (the process volume), the substrate 106 is exposed to the first ion and the first radical fluxes (box 408) for a first time duration.

The second plasma process of the process sequence 402 may be executed similar to the first plasma process. The vertical permeability may be adjusted again, in situ, this time to a second vertical permeability, as indicated in box 410 of the flowchart for the cyclic plasma process 400. A second ion flux and a second radical flux, based on the second vertical permeability of the stack, may be provided to the substrate 106 by generating a second plasma, and the substrate 106 is exposed to the second ion and second radical fluxes (box 414) for a second time duration. A difference between the first ion and radical fluxes and the second ion and radical fluxes is based on a difference between the first vertical permeability and the second vertical permeability.

The method outlined above for the cyclic plasma process 400 may be applied, for example, is patterning a layer to form a very high aspect ratio contact (HARC), where the aspect ratio may exceed 100. Sometimes, the very high aspect ratio contact hole is formed using a cyclic plasma etch process, for example, a Bosch process, used in fabricating a through-silicon via (TSV). A TSV is a conductive element connecting a feature on the front side of a silicon substrate to another on the backside of the substrate, for which a deep hole has to be etched through the substrate. Generally, one cycle of the Bosch process is a process sequence comprising three plasma processes. In a first plasma process of the process sequence, silicon is removed using anisotropic plasma etching to form a shallow recess. Here, a certain first ratio of ion-flux to radical-flux (Γᵢ/Γᵣ) may be appropriate and the positioning of the meshes may adjust the vertical permeability of the stack similar to the configuration illustrated for the mesh assembly in FIG. 1B to provide the desired first ratio of ion flux to radical flux. In the second plasma step, a low second ratio of ion flux to radical flux may be appropriate to deposit a conformal etch protection layer. So, the meshes may be positioned for zero vertical permeability, as in the configuration illustrated in FIG. 1C. In the third plasma step, ion-to-radical-flux ratio Γᵢ/Γᵣ needs to be increased to a third ratio of ion flux to radical flux to have a highly directional ion flux that removes the etch protection layer selectively from the bottomwall while leaving the sidewalls protected in preparation for further etching during the next cycle. Thus, the positioning may align the meshes for maximum vertical permeability, as shown in the configuration illustrated in FIG. 1A.

It is noted that, although the example plasma processing apparatus 100 is in an ICP configuration, the invention is not limited to embodiments where the plasma generation equipment of the plasma processing apparatus is configured in the ICP mode. Some other embodiment may have its plasma generation equipment configured in some other mode.

FIG. 5 illustrates a schematic view of a plasma processing apparatus 500, configured for capacitively coupled plasma (CCP). In a CCP configuration, there are two electrodes, often referred to as a top electrode and a bottom electrode, both electrodes being disposed in a vacuum chamber. One of the electrodes may be coupled to an EM power source (e.g., an RF source power source) while the other may be coupled to an RF bias source, a pulsed RF bias source, a pulsed DC bias, a DC bias, ground, or a combination thereof. Generally, each electrode is a planar structure, and is separated from the other by a fixed vertical distance.

As illustrated in FIG. 5, the plasma processing apparatus 500 is, in many respects, similar to the plasma processing apparatus 100 (shown in FIG. 1A). The plasma processing apparatus 500 has been derived from the processing apparatus 100 by modifying the plasma generation equipment 112 to a plasma generation equipment 512, as described below.

While in the ICP configuration the first electrode is an antenna outside the chamber, for example, the planar coil shaped first electrode 112A outside the chamber 104 (as shown in FIG. 1A), in the CCP configuration, the first electrode is a planar electrode, located in the chamber 104, where it may be exposed to the discharge gas. Accordingly, the first electrode 512A of the plasma generation equipment 512 is a disc-shaped first electrode located in the second portion 104B of the chamber 104 of the plasma processing apparatus 500, as illustrated in FIG. 5.

In the CCP configuration, the ICP antenna is replaced by the planar disc-shaped CCP electrode (e.g., the first electrode 512A), as described above. The chamber wall and one of the meshes of the stack may play the role of the second CCP electrode, if the mesh is a dielectric-coated metal. In the example embodiment illustrated in FIG. 5, the second mesh 108B may comprise a conductive material with an insulating coating (e.g., anodized aluminum, or metal coated with yttria) in order to function as the second electrode. The first electrode 512A and the second mesh 108B may be powered to generate plasma. As illustrated in FIG. 5, the first electrode 512A is coupled to the first EM power source 112B via the first impedance matching network 112C, and the second mesh 108B is coupled to another EM power source 512D via another impedance matching network 512E. The bias power, coupled to the wafer 106 to control the ion energy may remain the same. Accordingly, in the example plasma generation equipment 512 illustrated in FIG. 5, the RF bias source 112D is coupled to the substrate holder 102 via a second impedance matching network 112E, same as in the example illustrated in FIG. 1A. In various embodiments, the bias source may be an RF bias source, a pulsed RF bias source, a pulsed DC bias, a DC bias, ground, or a combination thereof.

In the CCP configuration for the plasma processing apparatus 500, the second portion 104B is the plasma reactor volume, same as in the ICP configuration for the plasma processing apparatus 100. Also, in both the plasma processing apparatus 500 and the plasma processing apparatus 100, the first portion 104A is the process volume.

Since the first electrode is inside the chamber, the top cover of the chamber, unlike the top cover 104C, is not constrained to be a non-conductor.

We have described, in this disclosure, embodiments of apparatus and methods to adjust the ion flux (Γᵢ) and the radical flux (Γᵣ), hence the ion-to-radical flux ratio (Γᵢ/Γᵣ) by positioning meshes of a mesh assembly comprising a stack of meshes inserted in a vacuum chamber used for the plasma processing. The embodiments provide a flexibility equivalent of changing the plasma source of the plasma processing apparatus at the fabrication facility. The adjustments may be done in situ (in addition to between two completely independent plasma processes). The capability of making in situ adjustments to plasma properties provides not only opportunities for tuning a plasma process during processing but also for performing in situ tool reconfiguration, which is useful for performing, for example, a cyclic plasma process having very different plasma processes in each cycle of the cyclic process.

Example embodiments of the invention are described below. Other embodiments can also be understood from the entirety of the specification as well as the claims filed herein.
Example 1. An apparatus for plasma processing a substrate, the apparatus including: a substrate holder configured to hold the substrate in a first portion of a vacuum chamber; a mesh assembly segregating the first portion from a second portion of the vacuum chamber along a vertical direction, the mesh assembly including a vertical stack of planar meshes; mesh positioning equipment configured to horizontally move one of the planar meshes to adjust a vertical permeability of the stack; and plasma generation equipment configured to generate plasma in the second portion of the vacuum chamber.
Example 2. The apparatus of example 1, where, when operated, the mesh positioning equipment adjusts the vertical permeability by varying a cross-sectional area of line-of-sight vertical paths passing through the stack via overlapping holes of the meshes.
Example 3. The apparatus of one of examples 1 to 2, where the mesh positioning equipment includes: movable parts mechanically coupled to the meshes, where the movable parts are configured to move one of the planar meshes in the associated plane of the mesh; and an actuator configured to move the movable parts.
Example 4. The apparatus of one of examples 1 to 3, where the plasma generation equipment is configured in an inductively coupled mode or a capacitively coupled mode.
Example 5. The apparatus of one of examples 1 to 4, where the plasma generation equipment includes: a gas flow system configured to flow gas through the vacuum chamber, the gas flow system including: a gas outlet coupled to the first portion of the chamber; and a gas inlet coupled to the second portion of the chamber; and a first electrode configured to couple electromagnetic (EM) power to the gas in the second portion of the chamber from a first EM power source coupled to the first electrode.
Example 6. The apparatus of one of examples 1 to 5, where the gas flow system further includes: an additional gas inlet coupled to the first portion of the chamber.
Example 7. The apparatus of one of examples 1 to 6, where the plasma generation equipment further includes: a second electrode coupled to a radio frequency (RF) bias source, a pulsed RF bias source a DC bias source, a pulsed DC bias source, ground, or a combination thereof, where the second electrode is included in the substrate holder, the stack of planar meshes, or a wall of the vacuum chamber.
Example 8. The apparatus of one of examples 1 to 7, where one of the planar meshes has a first region having a first density of holes and a second region having a second density of holes.
Example 9. The apparatus of one of examples 1 to 8, further including vertical positioning equipment configured to adjust a vertical position of the mesh assembly, where adjusting the vertical position adjusts a ratio of a volume of the first portion to a volume of the second portion.
Example 10. A method for plasma processing a substrate, the method including: positioning one of the planar meshes in the associated plane of the mesh, where the positioning adjusts a vertical permeability of the stack; loading a substrate on a substrate holder in a first portion of a vacuum chamber, the first portion being segregated from a second portion of the vacuum chamber along a vertical direction by a mesh assembly including a vertical stack of planar meshes; and after completing the positioning, exposing the substrate to an ion flux and a radical flux from a plasma generated in the second portion of the vacuum chamber, the ion flux and the radical flux being based on the vertical permeability of the stack.
Example 11. The method of example 10, where the positioning adjusts the vertical permeability by varying a cross-sectional area of line-of-sight vertical paths passing through the stack via overlapping holes of the meshes.
Example 12. The method of one of examples 10 to 11, where the positioning includes operating a mesh positioning equipment, the mesh positioning equipment including: movable parts mechanically coupled to the meshes, where the movable parts are configured to move one of the planar meshes in the associated plane of the mesh; and an actuator configured to move the movable parts.
Example 13. The method of one of examples 10 to 12, further including: having a controller configured to control the actuator; and sending control signals from the controller to the actuator to perform the positioning.
Example 14. The method of one of examples 10 to 13, where the positioning is performed prior to loading the substrate.
Example 15. The method of one of examples 10 to 14, where the positioning includes rotating one of the planar meshes in the associated plane of the mesh.
Example 16. The method of one of examples 10 to 15, where the positioning includes sliding one of the planar meshes in one direction in the associated plane of the mesh.
Example 17. The method of one of examples 10 to 16, where generating plasma in the vacuum chamber includes: introducing gas into the chamber through a gas inlet coupled to the second portion; ionizing the gas with electromagnetic (EM) power from a first electrode, the first electrode being configured to couple EM power to the gas in the chamber from a first EM power source coupled to the first electrode; and pumping gas out of the chamber through a gas outlet coupled to the first portion, the pumping directing the ion flux and the radical flux toward the substrate.
Example 18. The method of one of examples 10 to 17, where the plasma provides, in the first portion, a first ion density, a first electron temperature, a first radical density, an ion flux, and a radical flux directed from the mesh assembly to the substrate, and where the plasma provides a second ion density and a second electron temperature in the second portion, the second ion density being greater than the first ion density, and the second electron temperature being greater than the first electron temperature.
Example 19. The method of one of examples 10 to 18, where adjusting the vertical permeability adjusts a ratio of the ion flux to the radical flux from a maximum value of 75% to 95% of a reference value to a minimum value of a millionth to a trillionth of the reference value, where the reference value is the ratio of the ion flux to the radical flux without the mesh assembly.
Example 20. A method for plasma processing a substrate, the method including: loading a substrate on a substrate holder in a first portion of a vacuum chamber, the first portion being segregated from a second portion of the chamber along a vertical direction by a mesh assembly including a vertical stack of planar meshes, the stack having an adjustable vertical permeability; performing, in situ, a number of cycles of a process sequence, the sequence including: setting the vertical permeability of the stack to a first vertical permeability; exposing the substrate to a first ion flux and a first radical flux for a first time duration, the first ion and radical fluxes being based on the first vertical permeability; setting the vertical permeability of the stack to a second vertical permeability; and exposing the substrate to a second ion flux and a second radical flux for a second time duration, a difference between the first ion and radical fluxes and the second ion and radical fluxes being based on a difference between the first vertical permeability and the second vertical permeability.
Example 21. The method of example 20, where adjusting the vertical permeability includes positioning one of the planar meshes in the associated plane of the mesh, the positioning varying a cross-sectional area of line-of-sight vertical paths passing through the mesh assembly via overlapping holes of the meshes, where the positioning includes operating a mesh positioning equipment, the mesh positioning equipment including movable parts mechanically coupled to the meshes, where the movable parts are configured to move one of the planar meshes in the associated plane of the mesh, and an actuator configured to move the movable parts.
Example 22. The method of one of examples 20 to 21, where a ratio of the first ion flux to the first radical flux, is different from a ratio of the second ion flux to the second radical flux.
Example 23. The method of one of examples 20 to 22, where exposing the substrate to the first ion flux and the first radical flux removes material from the substrate; and where exposing the substrate to the second ion flux and the second radical flux deposits material on the substrate.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. An apparatus for plasma processing a substrate, the apparatus comprising:
a substrate holder configured to hold the substrate in a first portion of a vacuum chamber;
a mesh assembly segregating the first portion from a second portion of the vacuum chamber along a vertical direction, the mesh assembly comprising a vertical stack of planar meshes;
a mesh positioning equipment configured to horizontally move one of the planar meshes to adjust a vertical permeability of the stack; and
a plasma generation equipment configured to generate plasma in the second portion of the vacuum chamber.

2. The apparatus of claim 1, wherein, during operation, the mesh positioning equipment is configured to adjust the vertical permeability by varying a cross-sectional area of line-of-sight vertical paths passing through the stack via overlapping holes of the meshes.

3. The apparatus of claim 1, wherein the mesh positioning equipment comprises:
movable parts mechanically coupled to the meshes, wherein the movable parts are configured to move one of the planar meshes in the associated plane of the mesh; and
an actuator configured to move the movable parts.

4. The apparatus of claim 1, wherein the plasma generation equipment is configured in an inductively coupled mode or a capacitively coupled mode.

5. The apparatus of claim 1, wherein the plasma generation equipment comprises:
a gas flow system configured to flow gas through the vacuum chamber, the gas flow system comprising:
a gas outlet coupled to the first portion of the chamber, and
a gas inlet coupled to the second portion of the chamber, and
a first electrode configured to couple electromagnetic (EM) power to the gas in the second portion of the chamber from a first EM power source coupled to the first electrode.

6. The apparatus of claim 5, wherein the gas flow system further comprises:
an additional gas inlet coupled to the first portion of the chamber.

7. The apparatus of claim 5, wherein the plasma generation equipment further comprises:
a second electrode coupled to a radio frequency (RF) bias source, a pulsed RF bias source a DC bias source, a pulsed DC bias source, ground, or a combination thereof, wherein the second electrode is included in the substrate holder, the stack of planar meshes, or a wall of the vacuum chamber.

8. The apparatus of claim 1, further comprising a vertical positioning equipment configured to adjust a vertical position of the mesh assembly, wherein adjusting the vertical position adjusts a ratio of a volume of the first portion to a volume of the second portion.

9. A method for plasma processing a substrate, the method comprising:
positioning one of the planar meshes in the associated plane of the mesh, wherein the positioning adjusts a vertical permeability of the stack;
loading a substrate on a substrate holder in a first portion of a vacuum chamber, the first portion being segregated from a second portion of the vacuum chamber along a vertical direction by a mesh assembly comprising a vertical stack of planar meshes; and
after completing the positioning, exposing the substrate to an ion flux and a radical flux from plasma generated in the second portion of the vacuum chamber, the ion flux and the radical flux being based on the vertical permeability of the stack.

10. The method of claim 9, wherein the positioning adjusts the vertical permeability by varying a cross-sectional area of line-of-sight vertical paths passing through the stack via overlapping holes of the meshes.

11. The method of claim 9, wherein the positioning comprises operating a mesh positioning equipment, the mesh positioning equipment comprising:
movable parts mechanically coupled to the meshes, wherein the movable parts are configured to move one of the planar meshes in the associated plane of the mesh; and
an actuator configured to move the movable parts.

12. The method of claim 9, wherein the positioning is performed prior to loading the substrate.

13. The method of claim 9, wherein the positioning comprises rotating one of the planar meshes in the associated plane of the mesh.

14. The method of claim 9, wherein the positioning comprises sliding one of the planar meshes in one direction in the associated plane of the mesh.

15. The method of claim 9, wherein generating plasma in the vacuum chamber comprises:
introducing gas into the chamber through a gas inlet coupled to the second portion;
ionizing the gas with electromagnetic (EM) power from a first electrode, the first electrode being configured to couple EM power to the gas in the chamber from a first EM power source coupled to the first electrode; and
pumping gas out of the chamber through a gas outlet coupled to the first portion, the pumping directing the ion flux and the radical flux toward the substrate.

16. The method of claim 9, wherein the plasma provides, in the first portion, a first ion density, a first electron temperature, a first radical density, an ion flux, and a radical flux directed from the mesh assembly to the substrate, and wherein the plasma provides a second ion density and a second electron temperature in the second portion, the second ion density being greater than the first ion density, and the second electron temperature being greater than the first electron temperature.

17. The method of claim 9, wherein adjusting the vertical permeability adjusts a ratio of the ion flux to the radical flux from a maximum value of 75% to 95% of a reference value to a minimum value of a millionth to a trillionth of the reference value, wherein the reference value is the ratio of the ion flux to the radical flux without the mesh assembly.

18. A method for plasma processing a substrate, the method comprising:
loading a substrate on a substrate holder in a first portion of a vacuum chamber, the first portion being segregated from a second portion of the chamber along a vertical direction by a mesh assembly comprising a vertical stack of planar meshes, the stack having an adjustable vertical permeability;
performing, in situ, a number of cycles of a process sequence, the sequence comprising:
setting the vertical permeability of the stack to a first vertical permeability;
exposing the substrate to a first ion flux and a first radical flux for a first time duration, the first ion and radical fluxes being based on the first vertical permeability;
setting the vertical permeability of the stack to a second vertical permeability; and
exposing the substrate to a second ion flux and a second radical flux for a second time duration, a difference between the first ion and radical fluxes and the second ion and radical fluxes being based on a difference between the first vertical permeability and the second vertical permeability.

19. The method of claim 18,
wherein adjusting the vertical permeability comprises positioning one of the planar meshes in the associated plane of the mesh, the positioning varying a cross-sectional area of line-of-sight vertical paths passing through the mesh assembly via overlapping holes of the meshes,
wherein the positioning comprises operating a mesh positioning equipment, the mesh positioning equipment comprising
movable parts mechanically coupled to the meshes, wherein the movable parts are configured to move one of the planar meshes in the associated plane of the mesh, and
an actuator configured to move the movable parts.

20. The method of claim 18, wherein a ratio of the first ion flux to the first radical flux, is different from a ratio of the second ion flux to the second radical flux.
